(19) United States
(12) Patent Application Publication
(10) Pub. No.: US 2012/0011783 A1
(43) Pub. Date: Jan. 19, 2012

(54) Photovoltaic Devices and Photovoltaic Roofing Elements Including Granules, and Roofs Using Them

(76) Inventors: Gregory F. Jacobs, Oreland, PA (US); Wayne E. Shaw, Glen Mills, PA (US)

(21) Appl. No.: 13/243,631

(22) Filed: Sep. 23, 2011

Related U.S. Application Data
(63) Continuation of application No. 11/742,909, filed on May 1, 2007.

(51) Int. Cl. E04D 13/18; B32B 5/16; B32B 37/00; H01L 31/048

(52) U.S. Cl. 52/173.3; 136/251; 428/143; 156/60

(57) ABSTRACT

The present invention includes photovoltaic devices and photovoltaic roofing elements comprising a photovoltaic element having an active face and an operating wavelength range; a polymer structure having (a) a bottom surface disposed on the active face of the photovoltaic element and (b) a top surface; and a plurality of granules disposed on the top surface of the polymer structure. Roofs including the photovoltaic devices and photovoltaic roofing elements of the present invention may be configured to have an aesthetically desirable appearance while retaining high photovoltaic efficiency.

### BACKGROUND OF THE INVENTION

1. Field of the Invention

The present invention relates generally to photovoltaic devices. The present invention relates more particularly to photovoltaic devices with aesthetic properties making them suitable for use in roofing applications.

2. Technical Background

The search for alternative sources of energy has been motivated by at least two factors. First, fossil fuels have become more and more expensive due to increasing scarcity and unrest in areas rich in petroleum deposits. Second, there exists overwhelming concern about the effects of the combustion of fossil fuels on the environment, due to factors such as air pollution (from NOₓ, hydrocarbons and ozone) and global warming (from CO₂). In recent years, research and development attention has focused on harvesting energy from natural environmental sources such as wind, flowing water and the sun. Of the three, the sun appears to be the most widely useful energy source across the continental United States; most locales get enough sunshine to make solar energy feasible.

There are now available components that convert light energy into electrical energy. Such “photovoltaic cells” are often made from semiconductor-type materials such as doped silicon in either single crystalline, polycrystalline, or amorphous form. The use of photovoltaic cells on roofs is becoming increasingly common, especially as device performance has improved. They can be used, for example, to provide at least a fraction of the electrical energy needed for a building's overall function, or can be used to power one or more particular devices, such as exterior lighting systems.

Often perched on an existing roof in panel form, these photovoltaic elements are quite visible and generally not aesthetically pleasant. Photovoltaic elements generally have an overall black to purple appearance and are generally protected by a thin transparent glass or plastic cover. However, these colors frequently do not work well aesthetically with the rest of the roof. Nonetheless, to date, installations have appeared to have been motivated by purely practical and functional considerations; there appears to have been no coordination between the appearance of the photovoltaic cells and the roofing materials (e.g., tiles or shingles) upon which they are mounted. Lack of aesthetic appeal is especially problematic in residential buildings with non-horizontally pitched roofs; people tend to put a much higher premium on the appearance of their homes than they do on the appearance of their commercial buildings. While there have been attempts integrate photovoltaic elements into more conventional roofing materials, none appear to have addressed the fact that the photovoltaic element itself presents a generally aesthetically undesirable surface.

Accordingly, there remains a need for photovoltaic devices having more controllable and desirable aesthetics for use in roofing applications while retaining sufficient efficiency in electrical power generation.

### SUMMARY OF THE INVENTION

One aspect of the present invention is a photovoltaic device comprising a photovoltaic element having an active face and an operating wavelength range; a polymer structure having a bottom surface disposed on the active face of the photovoltaic element, and a top surface; and a plurality of granules disposed on the top surface of the polymer structure.

Another aspect of the invention is a photovoltaic roofing element including the above-described photovoltaic device.

Another aspect of the present invention is a photovoltaic roofing element comprising a roofing substrate having a top face and a bottom face; a photovoltaic element disposed on the top face of or within the roofing substrate, leaving an exposed area on the top face of the roofing substrate, the photovoltaic element having an operating wavelength range and an active face, the active face having an active area and an inactive area; a polymer structure having a bottom surface disposed on the exposed area on the top face of the roofing substrate, and a top surface; and a plurality of granules disposed on the top surface of the polymer structure.

Another aspect of the invention is a roof including one or more of the above-described photovoltaic devices and/or photovoltaic roofing elements disposed on a roof deck.

Another aspect of the invention is an integrated granule product comprising a polymer structure having a bottom surface and a top surface; and a plurality of granules disposed on the top surface of the polymer structure, wherein the combination of the granules and the polymer structure has at least about 50% energy transmissivity of solar radiation in the 400-750 nm wavelength range, the 650-1000 nm wavelength range, or the 450-1150 nm wavelength range.

Another aspect of the invention is a method of modifying a surface of a photovoltaic device, the method comprising disposing on the surface of the photovoltaic device a polymer structure, the polymer structure having a bottom surface and a top surface, the bottom surface being disposed on the surface of the photovoltaic device, the top surface having granules disposed thereon.

The photovoltaic devices, photovoltaic roofing elements, roofs and methods of the present invention result in a number of advantages over prior art methods. For example, the photovoltaic devices and photovoltaic roofing elements of the present invention can be configured to match, harmonize and/or complement a desired type of roofing material. The roofs of the present invention can be aesthetically pleasing yet still generate significant photovoltaic power.

Additional features and advantages of the invention will be set forth in the detailed description which follows, and in part will be readily apparent to those skilled in the art from the description or recognized by practicing the invention as described in the written description and claims hereof, as well as in the appended drawings.

It is to be understood that both the foregoing general description and the following detailed description are merely exemplary of the invention, and are intended to provide an overview or framework for understanding the nature and character of the invention as it is claimed.

The accompanying drawings are included to provide a further understanding of the invention, and are incorporated in and constitute a part of this specification. The drawings are not necessarily to scale, and sizes of various elements may be distorted for clarity. The drawings illustrate one or more embodiment(s) of the invention, and together with the description serve to explain the principles and operation of the invention.

### BRIEF DESCRIPTION OF THE DRAWINGS

FIG. 1 is a cross-sectional view of a photovoltaic device according to one embodiment of the present invention;

FIG. 2 is a graph showing the relative spectral response of three silicon-based photovoltaic materials as well as the spectral content of solar radiation;

FIG. 3 is a cross-sectional view of a photovoltaic device having a polymer structure having multiple layers according to one embodiment of the present invention;

FIG. 4 is a top perspective view of a photovoltaic roofing element based on an asphalt shingle according to one embodiment of the present invention;

FIG. 5 is a cross-sectional view of a single tab of the photovoltaic roofing element depicted in FIG. 4;

FIG. 6 is a top perspective view of a photovoltaic roofing element according to another embodiment of the present invention;

FIG. 7 is a cross-sectional view of the region surrounding one of the photovoltaic devices of the photovoltaic roofing element depicted in FIG. 6;

FIG. 8 is a cross-sectional view of a photovoltaic roofing element according to another embodiment of the invention;

FIG. 9 is a cross-sectional view of a photovoltaic roofing element according to another embodiment of the invention;

FIG. 10 is a cross-sectional view of a photovoltaic roofing element having a second polymer structure according to another embodiment of the invention;

FIG. 11 is a cross-sectional view of a photovoltaic roofing element in which the polymer structure and granules extend to cover the active area of the photovoltaic element according to another embodiment of the invention; and

FIG. 12 is a cross-sectional view of a granule-coated polymer structure according to another embodiment of the invention.

### DETAILED DESCRIPTION OF THE INVENTION

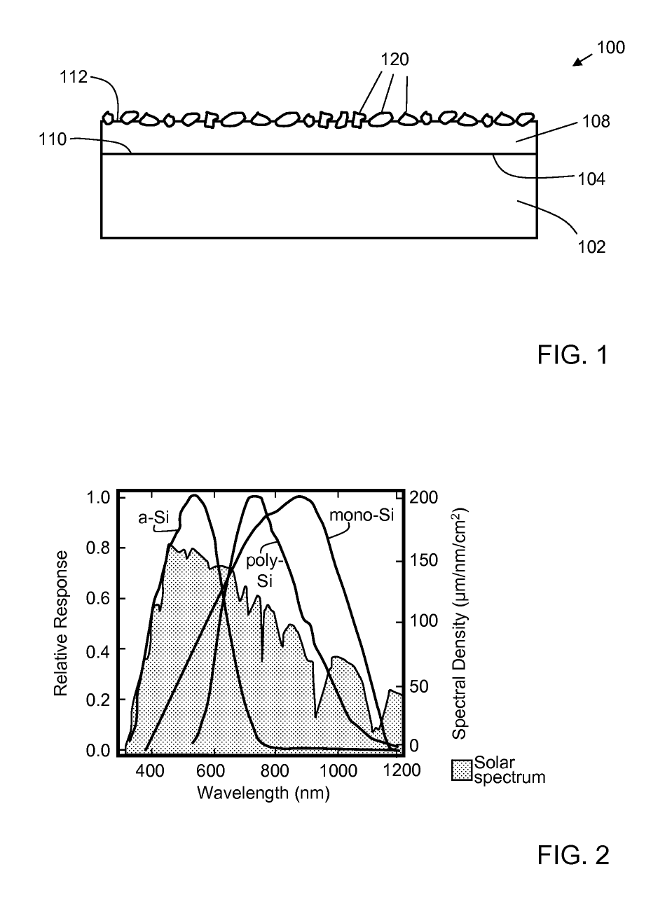

One aspect of the invention is a photovoltaic device. One example of a photovoltaic device according to this aspect of the invention is shown in schematic cross-sectional view in FIG. 1. Photovoltaic device 100 includes a photovoltaic element 102, which has an active face 104 and an operating wavelength range. Photovoltaic element 102 includes one or more photovoltaic cells individually electrically connected so as to operate as a single unit.

Photovoltaic element 102 may be based on any desirable photovoltaic material system, such as monocrystalline silicon; polycrystalline silicon; amorphous silicon; III-V materials such as indium gallium nitride; II-VI materials such as cadmium telluride; and more complex chalcogenides (group VI) and pnicogenides (group V) such as copper indium diselenide. For example, one type of suitable photovoltaic element includes an n-type silicon layer (doped with an electron donor such as phosphorus) oriented toward incident solar radiation on top of a p-type silicon layer (doped with an electron acceptor, such as boron), sandwiched between a pair of electrically-conductive electrode layers. As the skilled artisan will appreciate, other photovoltaic material systems can be used in the photovoltaic elements of the present invention. Photovoltaic element 102 may also include structural features such as a substrate (e.g., an ETFE or polyester backing, a glass plate, or an asphalt non-woven glass reinforced laminate such as those used in the manufacture of asphalt roofing shingles); one or more protectant or encapsulant materials (e.g., ETFE or EVA); one or more covering materials (e.g., glass or plastic); mounting structures (e.g., clips, holes, or tabs); and one or more optionally connectorized electrical cables. Thin film photovoltaic materials and flexible photovoltaic materials may be used in the construction of photovoltaic elements for use in the present invention. In one desirable embodiment of the invention, the photovoltaic element is a monocrystalline silicon element or a polycrystalline silicone photovoltaic element.

Photovoltaic element 102 desirably includes at least one antireflection coating, disposed on, for example, the very top surface of the photoelectric element or between individual protectant, encapsulant or covering layers.

Suitable photovoltaic elements may be obtained, for example, from China Electric Equipment Group of Nanjing, China, as well as from several domestic suppliers such as Uni-Solar, Sharp, Shell Solar, BP Solar, USFC, FirstSolar, General Electric, Schott Solar, Evergreen Solar and Global Solar.

Active face 104 of photovoltaic element 102 is the face presenting the photoelectrically-active areas of its one or more photoelectric cells. The active face may be the top surface of the one or more photovoltaic cells themselves, or more preferably may be the top surface of a series of one or more protectant, encapsulant and/or covering materials disposed thereon, as described above. As the skilled artisan will appreciate, during use of the photovoltaic device 100, active face 104 should be oriented so that it is illuminated by solar radiation, and any material covering it should be substantially non-opaque to radiation within the operating wavelength range of the photovoltaic element.

The photovoltaic element 102 also has an operating wavelength range. Solar radiation includes light of wavelengths spanning the near UV, the visible, and the near infrared spectra. As used herein, when the term “solar radiation” is used without further elaboration, it is meant to span the wavelength range of 300 nm to 1500 nm. As the skilled artisan will appreciate, different photovoltaic elements have different power generation efficiencies with respect to different parts of the solar spectrum. FIG. 2 is a graph showing the relative spectral response of three commonly-used photovoltaic materials as well as the spectral distribution of solar radiation. As the skilled artisan will recognize, amorphous doped silicon is most efficient at visible wavelengths, and polycrystalline doped silicon and monocrystalline doped silicon are most efficient at near-infrared wavelengths. As used herein, the operating wavelength range of a photovoltaic element is the wavelength range over which the relative spectral response is at least 10% of the maximal spectral response. According to certain embodiments of the invention, the operating wavelength range of the photovoltaic element falls within the range of about 300 nm to about 2000 nm. Preferably, the operating wavelength range of the photovoltaic element falls within the range of about 300 nm to about 1200 nm. For example, for photovoltaic devices having photovoltaic cells based on typical amorphous silicon materials the operating wavelength range is between about 375 nm and about 775 nm; for typical polycrystalline silicon materials the operating wavelength range is between about 600 nm and about 1050 nm; and for typical monocrystalline silicon materials the operating wavelength range is between about 425 nm and about 1175 nm.

As shown in FIG. 1, photovoltaic device 100 also includes a polymer structure 108. Polymer structure 108 has a bottom surface 110 disposed on the active face 104 of the photovoltaic element 102, and a top surface 112. The polymer structure may be formed from, for example, a single layer of a polymeric material, or multiple layers of polymeric materials. According to one embodiment of the invention, the polymer structure has an energy transmissivity to solar radiation of at least about 50% over the operating wavelength range of the photovoltaic element. As used herein, an “energy transmissivity to solar radiation of at least about 50% over the operating wavelength range of [a] photovoltaic element” means that at least about 50% of the total energy is transmitted when solar radiation within the operating wavelength range illuminates the polymer structure. The energy transmissivity at each wavelength in the operating wavelength range need not be at least about 50%. Desirably, the polymer structure has at least about 75% energy transmissivity to solar radiation over the operating wavelength range of the photovoltaic element. In certain especially desirable embodiments of the invention, the polymer structure has at least about 90% energy transmissivity to solar radiation over the operating wavelength range of the photovoltaic element. The skilled artisan will recognize that both the bulk properties and the thickness(es) of the material(s) of the polymer structure will influence the energy transmissivity of the polymer structure. In one embodiment of the invention, the polymer structure has a thickness from about 50 μm to about 2 mm. In certain desirable embodiments of the invention, the polymer structure has a thickness from about 75 μm to about 1 mm.

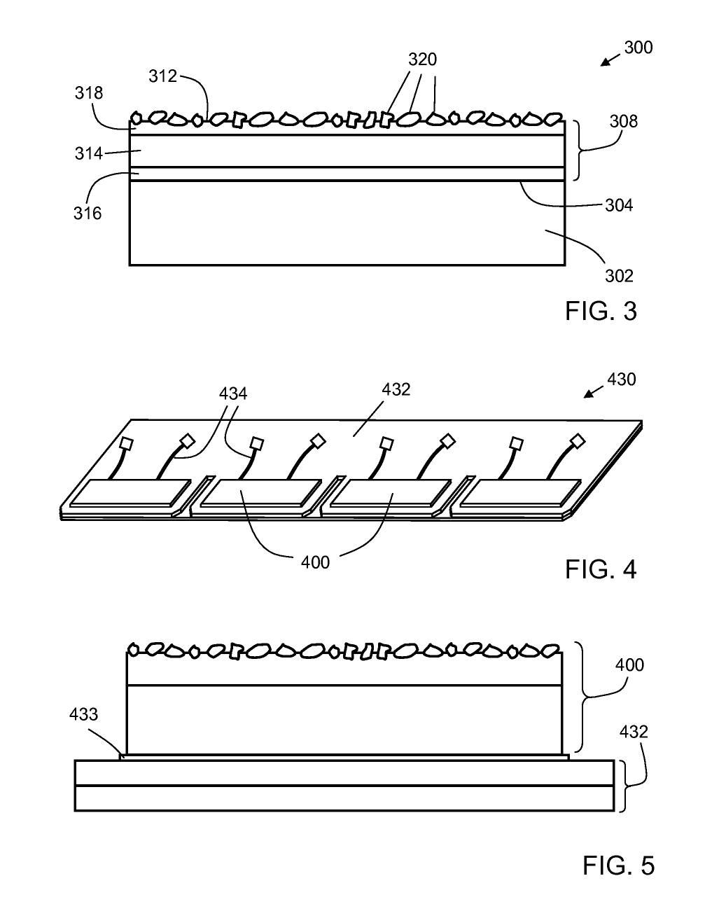

The polymer structure may be, for example, a single layer of polymer. The polymer structure may alternatively include multiple layers. Desirably, the layer distal to the active face of the photovoltaic element is an adhesive layer capable of adhering the granules to the top surface of the polymer structure. For example, as shown in FIG. 3, the polymer structure 308 may include three layers, including a structural supporting layer 314 (e.g., a 6-7 mil (˜150-175 μm) thick PET film); an adhesive layer 316 formed between the structural supporting layer 314 and the active face 304 of the photovoltaic element 302; and an adhesive layer 318 distal from the active face 304 of the photovoltaic element 302. As the skilled artisan will recognize, the polymer structure may have other numbers of layers. For example, it may have a two layer structure: a structural supporting layer, which is affixed to a polymeric protectant or encapsulant material of the photovoltaic element using heat and pressure; and an adhesive layer formed thereon. In some embodiments of the invention, the polymer structure on which the granules, described below, are disposed is the polymeric protectant, encapsulant and/or covering layer(s) formed on top of the photovoltaic cell(s) of the photovoltaic element itself. Other than the granules, described below, the polymer structure is desirably substantially free of particulate matter. In some embodiments of the invention, the polymer structure has a substantially flat top surface. However, in other embodiments of the invention, the top surface of the polymer structure is not substantially flat. For example, the top surface of the polymer structure may have a patterned surface relief, or may have a roughened surface relief. As the skilled artisan will appreciate, surface relief on the top surface of the polymer structure may be formed using standard techniques such as embossing or casting.

The top layer of the polymer structure (i.e., the layer distal from the photovoltaic cell(s)) is desirably an adhesive layer capable of adhering the granules, described below, to the top surface of the polymer structure. For example, the skilled artisan may use a two-part epoxy, a hot-melt thermoplastic, a heat-curable material or a radiation-curable material to form the adhesive layer. One particular example of a polymeric adhesive is the UV-cured product of a formulation consisting essentially of an acrylated urethane oligomer (e.g., EBECRYL 270, available from UCB Chemicals) with 1 wt % photoinitiator (e.g., IRGACURE 651 from Ciba Additives). Other suitable adhesive materials include ethylene-acrylic acid and ethylene-methacrylic acid copolymers, polyolefins, PET, polyamides and polyimides. Examples of suitable materials are described in U.S. Pat. Nos. 4,648,932, 5,194,113. 5,491,021 and 7,125,601, each of which is hereby incorporated herein by reference.

According to another embodiment of the invention, the polymer structure is colored, but has at least about 50% energy transmissivity to radiation over the 750-1150 nm wavelength range. As used herein, an item that is “colored” is one that appears colored (including white, black or grey, but not colorless) to a human observer. According to one embodiment of the invention, the polymer structure includes (either at one of its surfaces or within it) a near infrared transmissive multilayer interference coating designed to reflect radiation within a desired portion of the visible spectrum. In another embodiment of the invention, the polymer structure includes (either at one of its surfaces or within it) one or more colorants (e.g., dyes or pigments) that absorb at least some visible radiation but substantially transmit near-infrared radiation. The color(s) and distribution of the colorants may be selected so that the photovoltaic device has an appearance that matches, harmonizes with and/or complements a desired type of roofing material, such as asphalt shingles of a given color and design. The pattern of colorant may be, for example, uniform, or may be mottled in appearance. Ink jet printing, lithography, or similar technologies may be used to provide a pattern of colorant that approximates the appearance of the roofing materials to be used in conjunction with the photovoltaic device (e.g., granule-coated asphalt shingles). The polymer structure may include a pattern of colorant at, for example, the bottom surface of the polymer structure, the top surface of the polymer structure, or formed within the polymer structure. Desirably, when the polymer structure is colored, the majority of the operating range of the photovoltaic element is not within the 400-700 nm wavelength range.

Embodiments of the present invention having colored polymer structures are especially useful with photovoltaic elements having most of their photovoltaic activity in the near infrared, such as those based on polycrystalline silicon and monocrystalline silicon materials. In embodiments of the invention having colored polymer structures, the use of granules can provide an aesthetically desirable rough surface to the photovoltaic device, allowing it to more closely match a desired roofing material (e.g., an asphalt roofing shingle). Photovoltaic devices made with colored polymer structures are described in further detail in U.S. patent application Ser. No. 11/456,200, filed on Jul. 8, 2006 and entitled “Photovoltaic Device,” which is hereby incorporated herein by reference.

The photovoltaic devices according to this aspect of the invention also include a plurality of granules disposed on the top surface of the polymer structure. In the embodiments of the invention demonstrated in FIGS. 1 and 3, a plurality of granules 120 and 320 are disposed on the top surfaces 112 and 312 of the polymer structures 108 and 308, respectively. In certain embodiments of the invention, the granules are partially embedded in the top surface of the polymer structure, as shown in FIGS. 1 and 3.

As will be described in more detail below, the granules may be made of many different materials and take many different forms. As the skilled artisan will appreciate, the granules may be small particles, or alternatively may be more similar to gravel in size. Regardless of the identity of the granules, however, in certain embodiments of the invention, the granule type, the physical distribution of the granules, and the polymer structure are selected so that the combination of the polymer structure and the granules disposed thereon have an overall energy transmissivity to radiation (preferably solar) of at least about 40% over the operating wavelength range of the photovoltaic element. Desirably, the combination of the polymer structure and the granules disposed thereon have an overall energy transmissivity to radiation (preferably solar) of at least about 60% over the operating wavelength range of the photovoltaic element. In certain especially desirable embodiments of the invention, the combination of the polymer structure and the granules disposed thereon have an overall energy transmissivity to radiation (preferably solar) of at least about 80% over the operating wavelength range of the photovoltaic element.

In certain embodiments of the invention, the granules have a size in the range of 0.2 mm to 3 mm (taken in their greatest dimension). In other embodiments of the invention, the granules have a size in the range of 0.4 mm to 2.4 mm (e.g., about 1 mm). The granules may be roughly spherically symmetrical in shape (i.e., height˜length˜width), or may be more planar in shape (i.e., length˜width>height).

According to one embodiment of the invention, the granules are substantially opaque to solar radiation over the operating wavelength range of the photovoltaic element. For example, the granules may have less than 10% energy transmissivity to solar radiation over the operating wavelength range of the photovoltaic element. Such granules may be made from virtually any material that will withstand exposure to the environment without substantially degrading over a period of 10-20 years, e.g., for example, rock, mineral, gravel, sand, ceramic, or plastic. In certain especially desirable embodiments of the invention, the granules are ceramic-coated mineral core particles optionally colored with metal oxides, such as those used on asphalt roofing shingles. The mineral core can consist of any chemically inert matter that can support a ceramic layer and has adequate mechanical properties. For example, the mineral core can be formed from materials available in the natural state, such as talc, granite, siliceous sand, andesite, porphyry, marble, syenite, rhyolite, diabase, quartz, slate, basalt, sandstone, and marine shells, as well as material derived from recycled manufactured goods, such as bricks, concrete, and porcelain.

When the granules are substantially opaque to radiation, they are desirably disposed on the top surface of the polymer structure with a surface fill factor of no greater than about 75% over the active face of the photovoltaic element. The surface fill factor is the fraction of the active face of the photovoltaic element that is occluded by the granules, as measured in a direction normal to the active face of the photovoltaic element. Desirably, the granules have a surface fill factor of no greater than about 50%. In certain desirable embodiments of the invention, the granules have a surface fill factor of no greater than about 25%. The color(s) and distribution of the granules may random or as selected by the skilled artisan so that the photovoltaic device has an appearance that matches, harmonizes with and/or complements a desired type of roofing material, such as asphalt shingles of a given color and design.

According to another embodiment of the invention, the granules are at least partially transmissive to radiation (preferably solar) over the operating wavelength range of the photovoltaic element. For example, in one embodiment of the invention, the partially transmissive granules have at least about 50% energy transmissivity to radiation (preferably solar) over the operating wavelength range of the photovoltaic element. Desirably, the partially transmissive granules have at least about 75% energy transmissivity to radiation (preferably solar) over the operating wavelength range of the photovoltaic element. In certain especially desirable embodiments of the invention, the partially transmissive granules have at least about 90% energy transmissivity to radiation (preferably solar) over the operating wavelength range of the photovoltaic element. At least partially transmissive granules can be formed from glass, such as in the form of cullet or beads. At least partially transmissive granules can also be formed from, for example, from quartz, sand, non-vitreous ceramics such as those described in U.S. Pat. Nos. 4,349,456, 4,565,556 and 4,605,594, each of which is hereby incorporated herein by reference, or polymeric materials such as polypropylene, poly(ethylene terephthalate), poly(propylene oxide), acrylic polymers, or polysulfone. The partially transmissive granules may be treated with an adhesion promoter in order to enhance their adhesion to the top surface of the polymer structure. In certain desirable embodiments of the invention, the partially transmissive granules are coated with an anti-reflective layer (e.g., using fluidized bed coating processes such as those described in U.S. Patent Application Publication no. 2006/0251807, which is hereby incorporated herein by reference, and/or conventional pan-coating processes). Desirably, the partially transmissive granules have an index of refraction that is closely matched to the index of refraction of the polymeric structure at its top surface. For example, the difference between the n_{D} value of the partially transmissive granule and the n_{D} value of the polymeric structure at its top surface is desirably less than about 0.1, and more desirably less than about 0.05. In certain embodiments of the invention, the partially transmissive granules are substantially spherical in shape, so as to function as lenses guiding light to the active face of the photovoltaic element.

Because the granules according to this embodiment transmit radiation, they may generally be disposed on the polymer structure with much higher surface fill factors compared to opaque granules. For example, according to one embodiment of the invention, the partially transmissive granules have a surface fill factor of greater than about 50%. In certain desirable embodiments of the invention, the partially transmissive granules have a surface fill factor of greater than about 75%. The use of partially transmissive granules can provide surface relief to a photovoltaic device, providing more desirable aesthetic qualities when compared with the generally flat surface of a conventional photovoltaic device.

According to another embodiment of the invention, at least some of the granules are opaque to at least some visible radiation, but have at least about 50% energy transmissivity of radiation over the 750-1150 nm wavelength range. Such granules may be, for example, partially transmissive granules (as described above) coated with a near infrared transmissive coating. The near infrared transmissive coating may be, for example, a polymeric ink having a colorant (e.g., a dye or a pigment) that absorbs visible radiation. Alternatively, the near infrared transmissive coating may be a multilayer interference coating designed to reflect a radiation within a desired portion of the visible spectrum. Pigments with high near infrared transmissivity include pearlescent pigments, light-interference platelet pigments, ultramarine blue, ultramarine purple, cobalt chromite blue, cobalt aluminum blue, chrome titanate, nickel titanate, cadmium sulfide yellow, cadmium sulfoselenide orange, and organic pigments such as phthalo blue, phthalo green, quinacridone red, diarylide yellow, and dioxazine purple. The color(s) and distribution of the infrared transmissive granules may be selected so that the photovoltaic device has an appearance that matches, harmonizes with, and/or complements a desired type of roofing material, such as granule-coated asphalt shingles of a given color and design. Desirably, when the granules are colored, the majority of the operating range of the photovoltaic is not within the 400-700 nm wavelength range. Embodiments of the present invention having colored granules are especially useful with photovoltaic elements having operating wavelength ranges that include the near-infrared, such as those based on polycrystalline silicon and monocrystalline silicon materials.

It may be desirable to use more than one type of granule in the photovoltaic devices of the present invention. For example, in some embodiments of the invention, a mixture of opaque and at least partially transmissive granules are used in order to achieve a desired balance of appearance and transmissivity. Of course, as the skilled artisan would appreciate, multiple colors of granules may also be used to achieve a desired aesthetic effect. Similarly, different zones of the photovoltaic device may be covered with granules of different composition, color and/or distribution. For example, the active area of the active face of the photovoltaic element might be covered with granules of one color/composition/distribution, while the remainder of the device is covered with granules of another color/composition/distribution. Using different granules in different zones allows the skilled artisan to maximize transmission of solar radiation to the active area, while maintaining a desirable appearance and cost for the overall device. U.S. Patent Application Publication no. 2006/0260731, which is hereby incorporated herein by reference, describes methods useful in the manufacture of multi-granule roofing materials; these methods can be adapted by the skilled artisan for use in the present invention.

When the photovoltaic device is relatively thick, it may be desirable for the polymer structure and the granules disposed thereon to cover not only its active face, but also one or more of its edge faces, so as to impart to it a desired appearance when it is installed on a roof. The edge faces would be especially visible when the photovoltaic device is installed on a non-horizontally pitched roof; accordingly, when such an installation is contemplated it may be especially desirable to cover one or more edge faces of the photovoltaic element with a polymer structure and granules substantially as described herein.

One or more of the photovoltaic devices described above may be installed on a roof as part of a photovoltaic system for the generation of electric power. Accordingly, one aspect of the invention is a roof comprising one or more photovoltaic devices as described above disposed on a roof deck. The photovoltaic devices are desirably connected to a photovoltaic system, either in series, in parallel, or in series-parallel, as would be recognized by the skilled artisan.

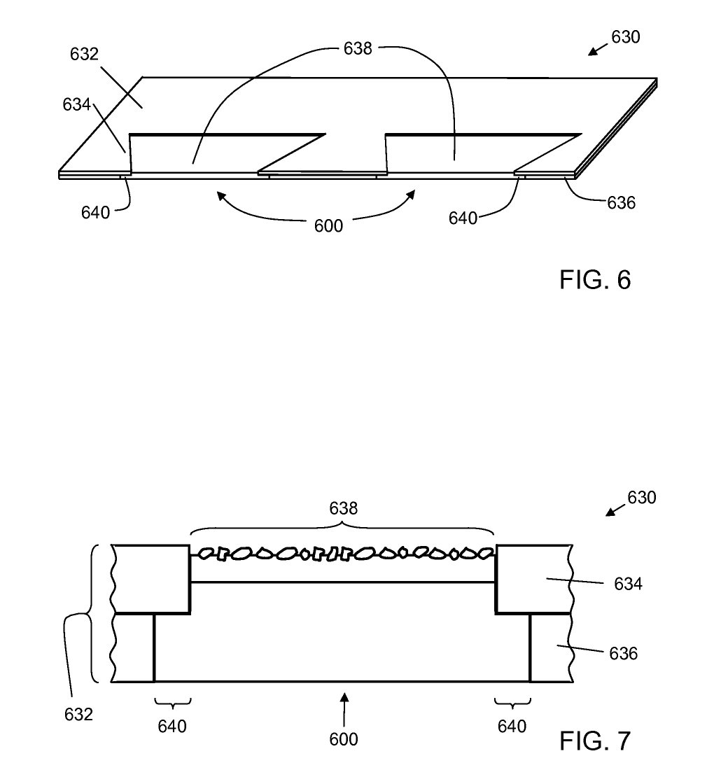

Because the photovoltaic devices of the present invention are desirably used on a roof, it may be desirable to incorporate them with a roofing material. Accordingly, one aspect of the invention is a photovoltaic roofing element comprising one or more photovoltaic devices as described above disposed on or within a roofing substrate. Roofing substrates suitable for use in this aspect of the invention include, for example, shingles, tiles, panels, membranes and shakes. As used herein, a photovoltaic device disposed “on” a roofing substrate is disposed on a top surface of the roofing substrate (as described below in more detail with reference to FIGS. 4 and 5), while a photovoltaic device disposed “within” a roofing substrate is disposed on a bottom or side surface of the roofing substrate, with the active area of its photovoltaic element being exposed to face the same direction as the top surface of the roofing substrate (as described below in more detail with reference to FIGS. 6 and 7).

Another embodiment of the invention is shown in perspective top view in FIG. 4, and in partial cross-sectional view in FIG. 5. Photovoltaic roofing element 430 includes four photovoltaic devices 400 substantially as described above, disposed on a roofing substrate 432. In the embodiment of the invention shown in FIGS. 4 and 5, the roofing substrate 432 is a dual-layer multi-tab asphalt roofing shingle; the cross-sectional view of FIG. 5 is of a single tab. In the embodiment of the invention shown in FIG. 4, each of the photovoltaic devices has a pair of connectorized electrical cables 434 that remain disposed on top of the roofing substrate 432; they may be connected into an electrical system and covered by the tabs of the next course of shingles. The skilled artisan will recognize that any electrical cables in the photovoltaic elements may be routed in many different ways. For example, they can run through a hole in the roofing substrate and be potted in by roofing compound; or be integrated into the roofing substrate itself. The photovoltaic device may be attached to the roofing substrate using adhesive (as demonstrated in FIG. 5 by adhesive layer 433), or alternatively may be screwed, clipped, or nailed to the roofing substrate or to the roof deck, as would be appreciated by the skilled artisan. The color(s) and distribution of the granules may be selected by the skilled artisan so that the photovoltaic devices have an appearance that matches, harmonizes with and/or complements that of the asphalt roofing shingle.

While the embodiment of FIGS. 4 and 5 is based on an asphalt roofing shingle, the skilled artisan will appreciate that any desirable roofing substrate may be used in the photovoltaic roofing elements of the present invention. For example, in certain embodiments of the invention, the roofing substrate is a roofing membrane, a ceramic tile, or a metal panel.

Another embodiment of the invention is shown in perspective top view in FIG. 6 and in cross-sectional view in FIG. 7. For simplicity, only a portion in the neighborhood of one of the photovoltaic elements is shown in FIG. 7. Photovoltaic roofing element 630 includes two photovoltaic devices 600 substantially as described above disposed within a roofing substrate 632. In the embodiment of the invention shown in FIGS. 6 and 7, the roofing substrate 632 is a two layer laminated asphalt roofing shingle, having a top layer 634 and a bottom layer 636. The photovoltaic devices 600 have an exposed area 638, and recessed attachment surfaces 640 along their three sides that are attached to roofing substrate 632. The top layer 634 of roofing substrate is affixed to the attachment surface 640, preferably in a watertight fashion using a suitable adhesive (e.g., asphalt, roofing compound). The bottom layer 636 of the roofing substrate is desirably roughly equivalent in thickness to the attachment surface 640 so that the top layer 634 of the roofing substrate 632 appears relatively flat. The entire area of the exposed area 638 is desirably covered with granules. The color(s) and distribution of the granules may be selected by the skilled artisan so that the photovoltaic devices have an appearance that matches, harmonizes with and/or complements that of the asphalt roofing shingle.

While the embodiments described with reference to FIGS. 4-7 have two-layer shingles as their roofing substrates, the skilled artisan will appreciate that more or fewer layers may used. For example, more layers may help improve stability and help better accommodate the thickness of the photovoltaic element. As the skilled artisan will appreciate, additional layers (and partial layers) of shingle material may be used for other purposes, such as to meet aesthetic, mechanical, or weatherproofness requirements. Of course, a single layer of asphalt shingle material may be used as the roofing substrate.

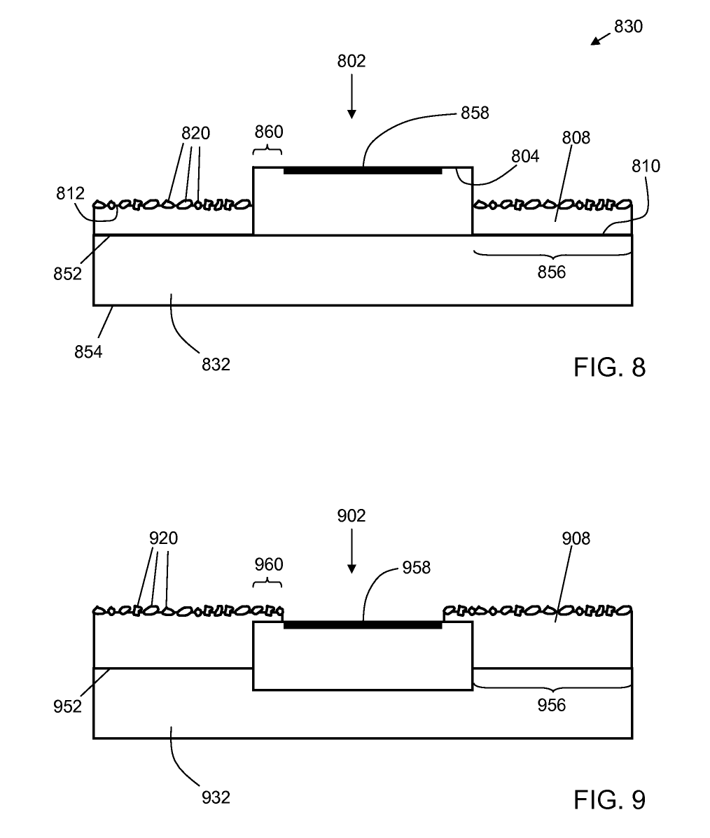

Another aspect of the invention is a photovoltaic roofing element as shown in cross-sectional view in FIG. 8. Photovoltaic roofing element 830 includes a roofing substrate 832 having a top face 852 and a bottom face 854. The roofing substrate may be, for example, an asphalt non-woven glass reinforced laminate (e.g., an asphalt roofing shingle without the conventional top layer of ceramic-coated inorganic granules). A photovoltaic element 802 is disposed on the top face 852 of the roofing substrate 832, leaving an exposed area 856 (i.e., not covered by the photovoltaic element) on the top face 852 of the roofing substrate 832. The photovoltaic element may also be disposed within the roofing substrate, as described above. Desirably, the photovoltaic element includes near its top surface at least one waterproof protectant, encapsulant or covering layer. The photovoltaic element 802 has an active face 804 and an operative wavelength range, as described above. The active face 804 has an active area 858 and an inactive area 860. The active area is the area over which incident light can cause photovoltaic power generation (i.e., where the photovoltaic cells are presented), and the inactive area is any area over which incident light cannot cause photovoltaic power generation. Polymer structure 808, substantially as described above, has a bottom surface 810 disposed on the exposed area 856 of the top face 852 of the roofing substrate 832, as well as a top surface 812. A plurality of granules 820 are disposed on the top surface 812 of the polymer structure 808. In the embodiment of FIG. 8, the granules 820 and the polymer structure 808 need not transmit light in the operating wavelength range of the photovoltaic device, and therefore may be formed from any desirable material, as described in further detail below.

According to one embodiment of the invention, the granules disposed on the top surface of the polymer structure over the exposed area of the roofing substrate are desirably substantially opaque to ultraviolet radiation and are colored. When the roofing substrate is an asphalt non-woven glass reinforced laminate having no other granules thereon, granules that are opaque to ultraviolet radiation and are colored can help prevent the photodegradation of the asphalt material, as would be appreciated by the skilled artisan. For example, the granules may be substantially opaque to solar radiation. Such granules may be made from, for example, rock, mineral, gravel, sand, ceramic, or plastic. In certain especially desirable embodiments of the invention, the granules are ceramic-coated mineral particles optionally colored with metal oxides, such as those used on conventional asphalt roofing shingles. Alternatively, the granules may be colored, but have at least about 50% energy transmissivity of solar radiation over the 750-1150 nm wavelength range, as described above. When the granules are substantially opaque to ultraviolet radiation and are colored, they desirably have a surface fill factor of greater than about 50%. In certain desirable embodiments of the invention, the granules have a surface fill factor of greater than about 75%.

According to another embodiment of the invention, the polymer structure itself is substantially opaque to ultraviolet radiation and is colored. The polymer structure may be substantially opaque to solar radiation, and may be based on, for example, a pigmented polymer sheet. Alternatively, the polymer structure may be a colored polymer structure as described above.

In certain embodiments of the invention, the polymer structure does not extend to cover the active area of the active face of the photovoltaic element. It may, however, extend to cover at least part of the inactive area of the active face of the photovoltaic element. As shown in cross-sectional view in FIG. 9, polymer structure 908 and granules 920 cover not only the exposed area 956 of the top surface 952 of the roofing substrate, but also most of the inactive area 960 of the active face 904 of the photovoltaic element 902. The granules 920 do not cover the active area 958 of the active face 904 of the photovoltaic element 902. In the embodiment of FIG. 9, the photovoltaic element 902 is embedded in the top surface 952 of the roofing substrate 932. In embodiments of the invention in which the polymer structure does not cover the active area of the active face of the photovoltaic element, it may be desirable to use polymer structures and/or granules that are substantially opaque to ultraviolet radiation and are colored, as described above.

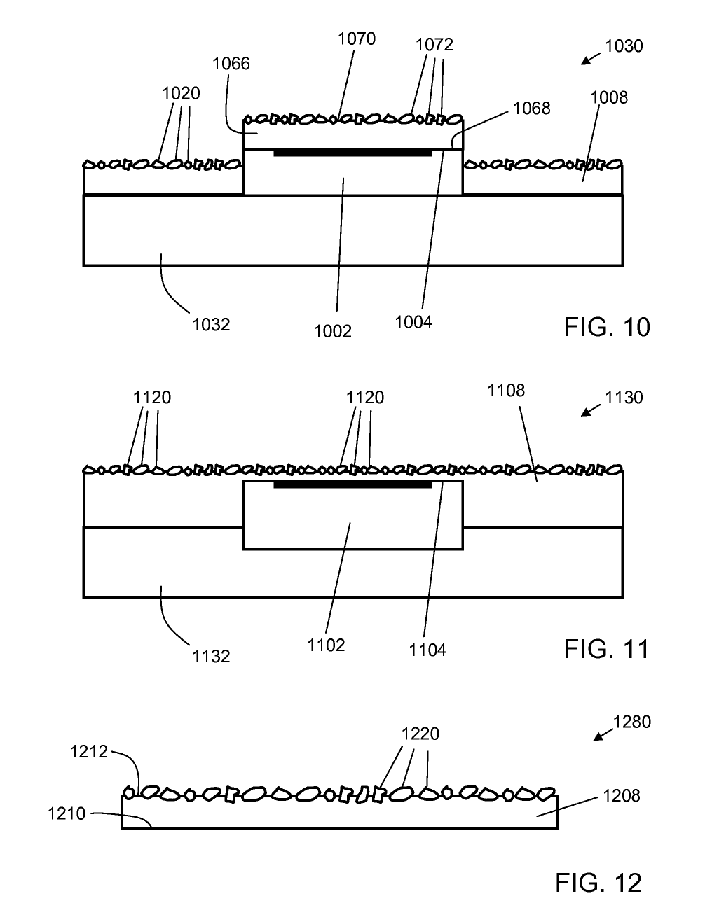

When the polymer structure does not extend to cover the active area of the active face of the photovoltaic element, it may be desirable for the photovoltaic element to have its own polymer structure and granules disposed on it, substantially as described above. For example, FIG. 10 is a cross-sectional view of a photovoltaic roofing element 1030, in which photovoltaic element 1002 has an active face 1004. Photovoltaic roofing element 1030 also includes a roofing substrate 1032, a polymer structure 1008, and a plurality of granules 1020 substantially as described above with reference to FIG. 8. A second polymer structure 1066 has a bottom surface 1068 disposed on the active face 1004 of the photovoltaic element 1002, and a top surface 1070. The photovoltaic roofing element 1030 further includes a second plurality of granules 1072 disposed on the top surface 1070 of the second polymer structure 1066. As shown in FIG. 10, the second polymer structure and second plurality of granules may cover the entire active face of the photovoltaic element. Alternatively, in another embodiment of the invention, the second polymer structure covers only the active area of the active face of the photovoltaic element, with the polymer structure that is disposed on the exposed face of the roofing element extending to cover any inactive area as described above with reference to FIG. 9. In the embodiment of FIG. 10, the granules 1020 and the polymer structure 1008 need not transmit light in the operating wavelength range of the photovoltaic device, and therefore may be formed from any desirable material, as described above.

When the photovoltaic roofing element includes a second plurality of granules 1072, they desirably have the properties described above with respect to the photovoltaic devices according to the first aspect of the invention (e.g., FIGS. 1 and 3-7). For example, in one embodiment of the invention the granules of the second plurality of granules are substantially opaque to radiation over the operating wavelength range of the photovoltaic element, and have a surface fill factor of no greater than about 75% over the active face of the photovoltaic element. Desirably, they have a surface fill factor of no greater than about 50%, and in certain especially desirable embodiments of the invention, they have a surface fill factor of no greater than about 25%. The opaque granules may be, for example, ceramic-coated inorganic particles. In another embodiment of the invention, the granules are at least partially transmissive to radiation over the operating wavelength range of the photovoltaic element. For example, the granules may transmit at least about 50% or at least about 75% of radiation (preferably solar) over the operating wavelength range of the photovoltaic element. Such partially transmissive granules may be made from, for example, quartz, sand, glass (e.g., in the form of cullet or beads), non-vitreous ceramics, such as those described in U.S. Pat. Nos. 4,349,456, 4,565,556 and 4,605,594, each of which is hereby incorporated herein by reference, or polymeric materials such as polypropylene, poly(ethylene terephthalate), poly(propylene oxide), acrylic polymers, or polysulfone. In another embodiment of the invention, the partially transmissive granules are opaque to at least some visible radiation but have at least about 50% energy transmissivity to radiation (preferably solar) over the 750-1150 nm wavelength range. Such granules may be, for example, substantially transparent particles having IR-transmissive coatings. The granules of the second plurality of granules desirably have a size in the range of 0.2 mm to 3 mm (taken in their greatest dimension). In other embodiments of the invention, the granules of the second plurality of granules have a size in the range of 0.4 mm to 2.4 mm (e.g., about 1 mm).

These granules may be roughly spherically symmetrical in shape (i.e., height˜length˜width), or may be more planar in shape (i.e., length˜width>height).

When the photovoltaic roofing element includes a second polymer structure, it desirably has the properties described above with respect to the photovoltaic devices according to the first aspect of the invention (e.g., FIGS. 1 and 3-7). For example, the second polymer structure may be a single layer of polymer adhesive, or include multiple layers. The second polymer structure desirably has an energy transmissivity of at least about 50%, at least about 75%, or at least about 90% over the operating wavelength range of the photovoltaic element. The second polymer structure desirably has a thickness of from about 50 μm to about 2 mm, or from about 75 μm to about 1 mm. In another embodiment of the invention, the second polymer structure is colored but has at least about 50% energy transmissivity of solar radiation in the 750-1150 nm wavelength range. Desirably, the combination of the second polymer structure and the granules disposed thereon has an overall energy transmissivity to radiation (preferably solar) of at least about 40%, at least about 60%, or at least about 80% over the operating wavelength range of the photovoltaic element.

According to another embodiment of the invention, shown in FIG. 11, the polymer structure extends to cover the active area of the active face of the photovoltaic element as well as the exposed area of the roofing substrate. In FIG. 11, photovoltaic roofing element 1130 includes a photovoltaic element 1102, and a roofing substrate 1132 as described above with respect to FIG. 9. Photovoltaic roofing element 1130 also includes a polymer structure 1108 that extends to cover not only the exposed area of the roofing substrate, but also the entire active face 1104 of the photovoltaic element 1102. A plurality of granules 1120 is disposed on the top face of the polymer structure 1108 over its entire area. In one embodiment of the invention, the granules disposed on the polymer structure above the active area of the active face of the photovoltaic element have substantially the same composition and surface fill factor as the granules disposed on the polymer structure above the roofing substrate.

When the polymer structure extends over the active area of the active face of the photovoltaic element, it desirably has the properties described above with respect to the second polymer structure. When the granules are disposed on the polymer structure over the active area of the photovoltaic element, they desirably have the properties described above with respect to the second plurality of granules.

In the embodiment of FIG. 11, the plurality of granules is disposed on the polymer structure over its entire top face. However, in other embodiments, the granules may be disposed on only on parts of the top face of the polymer structure. For example, in one embodiment of the invention, granules are disposed on the top face of the polymer structure over the exposed area of the roofing substrate, but not over the active area of the active face of the photovoltaic element. In such cases, the polymer structure is desirably colored in the area of the active area. The identity and distribution of the color(s) in the area of the active area may be selected by the skilled artisan to match, harmonize and/or complement the appearance of the granule-coated polymer structure disposed over the exposed area of the roofing substrate.

In another embodiment of the invention, the granules disposed on the polymer structure over the active area of the photovoltaic element are different in color distribution, surface fill factor, and/or composition than the granules disposed on the polymer structure over the exposed area of the roofing substrate. The colors, composition and distribution of the granules may be chosen by the skilled artisan so that the appearance of the active face of the photovoltaic element matches, harmonizes with and/or complements that of the exposed area of the roofing substrate.

For example, in one embodiment of the invention, the granules disposed on the polymer structure over the active area of the photovoltaic element are glass cullet; and the granules disposed on the polymer structure over the exposed area of the roofing substrate are ceramic-coated inorganic granules with a surface fill factor of greater than about 50%. In this embodiment of the invention, the polymer structure over the active area of the photovoltaic element is desirably colored so that it matches, harmonizes with, and/or complements the appearance of the ceramic-coated granules disposed on the polymer structure over the exposed area of the roofing substrate.

In the embodiments described above with reference to FIGS. 10 and 11, the granule color, composition and/or distribution can vary between zones on the photovoltaic roofing element. As described above, using different granules in different zones allows the skilled artisan to maximize transmission of solar radiation to the active area, while maintaining a desirable appearance and cost for the overall device.

In another embodiment of the invention, the polymer structure provides a cover for electrical cables connected to the photovoltaic element. For example, in one embodiment of the invention (e.g., as shown in FIG. 4), the photovoltaic roofing element includes one or more electrical cables operatively coupled to the photovoltaic element. These electrical cables may be used to interconnect individual photovoltaic elements within a single photovoltaic roofing element, and/or interconnect one or more photovoltaic roofing elements into a photovoltaic system. The cables may optionally be connectorized. The cables and any connectors desirably meet UNDERWRITERS LABORATORIES (UL) and NATIONAL ELECTRICAL CODE (NEC) standards for safety. In certain embodiments of the invention, the cables and any connectors are selected to withstand loads of up to 600 VDC at 2-10 amperes. The one or more electrical cables are at least in part disposed between the top face of polymer structure and the top face of the roofing substrate. In certain desirable embodiments of the invention, the roofing substrate has a channel formed therein, and the one or more electrical cables are at least partially disposed in the channel and are covered by the polymer structure. The polymer structure may simply cover the one or more electrical cables, or may partially or completely encapsulate them.

The photovoltaic devices and photovoltaic roofing elements described above are generally installed as arrays of photovoltaic devices or photovoltaic roofing elements. Accordingly, another aspect of the invention is an array of photovoltaic devices or photovoltaic roofing elements as described above. As the skilled artisan will appreciate, the array can include any desirable number of photovoltaic devices or photovoltaic roofing elements, which can be arranged in any desirable fashion. For example, the array can be arranged as partially overlapping, offset rows of photovoltaic devices or photovoltaic roofing elements, in a manner similar to the conventional arrangement of roofing materials. The photovoltaic devices or photovoltaic roofing elements within the array can be electrically connected in series, in parallel, or in series-parallel, as would be evident to the skilled artisan. In one embodiment of the invention, the array of photovoltaic devices or photovoltaic roofing elements is fixed in a frame system similar to that used in conventional rooftop photovoltaic modules.

One or more of the photovoltaic devices and/or photovoltaic roofing elements described above may be installed on a roof as part of a photovoltaic system for the generation of electric power. Accordingly, one aspect of the invention is a roof comprising one or more photovoltaic devices as described above disposed on a roof deck. Another aspect of the invention is a roof comprising one or more photovoltaic roofing elements as described above disposed on a roof deck. The photovoltaic elements of the photovoltaic devices and/or photovoltaic roofing elements are desirably connected to a photovoltaic system, either in series, in parallel, or in series-parallel, as would be recognized by the skilled artisan. Electrical connections are desirably made using cables, connectors and methods that meet UL and NEC standards.

Photovoltaic roofing elements of the present invention may be fabricated using many techniques familiar to the skilled artisan. The polymer structures may be fabricated, for example, using the methods described in U.S. Pat. Nos. 5,194,113 and 7,125,601, or using doctor blading, laminating, and/or molding techniques familiar to the skilled artisan. For example, when the roofing substrate is an asphalt shingle or an asphalt non-woven glass reinforced laminate, the methods described in U.S. Pat. Nos. 5,953,877; 6,237,288; 6,355,132; 6,467,235; 6,523,316; 6,679,308; 6,715,252; 7,118,794; U.S. Patent Application Publication 2006/0029775; and International Patent Application Publication WO 2006/121433. Each of the patents and publications referenced above is hereby incorporated herein by reference in its entirety. Photovoltaic roofing elements may be fabricated in a continuous process and then cut into individual elements as is done in the fabrication of asphalt shingles. When a continuous process is used, it may be necessary to individually prepare any electrical cables running between elements, for example by cutting the cables between elements and connectorizing the cut ends.

Another aspect of the invention is a granule-coated polymer structure, an example of which is shown in cross-sectional view in FIG. 12. Granule-coated polymer structure 1280 includes a polymer structure 1208 having a top surface 1212 and a bottom surface 1210. The top surface 1212 has a plurality of granules 1220 disposed on it, as described above with respect to the photovoltaic devices and photovoltaic roofing elements of the present invention. The polymer structure and the plurality of granules are chosen so that their combination has at least about 40% energy transmissivity of radiation over the 400-750 nm wavelength range, the 650-1000 nm wavelength range, or the 450-1150 nm wavelength range. Granule-coated polymer structures according to this aspect of the invention may be useful in manufacturing roofing elements, as described above. Granule-coated polymer structures according to this aspect of the invention may be fabricated, for example, using the methods described in U.S. Pat. Nos. 5,194,113 and 7,125,601, as well as those familiar to the skilled artisan.

The polymer structure desirably has the properties described above with respect to the photovoltaic devices according to the first aspect of the invention. For example, the polymer structure may be a single layer of polymer, or include multiple layers. The polymer structure desirably has an energy transmissivity of at least about 50%, at least about 75%, or at least about 90% over the operating wavelength range of the photovoltaic element. The polymer structure desirably has a thickness of from about 50 μm to about 2 mm, or from about 75 μm to about 1 mm. In another embodiment of the invention, the polymer structure is colored but has at least about 50% energy transmissivity of radiation in the 750-1150 nm wavelength range.

The granules desirably have the properties described above with respect to the photovoltaic devices according to the first aspect of the invention. For example, in one embodiment of the invention the granules are substantially opaque to radiation over the operating wavelength range of the photovoltaic element, and have a surface fill factor of no greater than about 75% over the active face of the photovoltaic element. Desirably, they have a surface fill factor of no greater than about 50%, and in certain especially desirable embodiments of the invention, they have a surface fill factor of no greater than about 25%. The opaque granules may be, for example, ceramic-coated inorganic particles. In another embodiment of the invention, the granules are at least partially transmissive to radiation over the operating wavelength range of the photovoltaic element. For example, the granules may transmit at least about 50% or at least about 75% of solar radiation over the operating wavelength range of the photovoltaic element. Such granules may be made from, for example, quartz, sand, glass (e.g., in the form of cullet or beads), non-vitreous ceramics, such as those described in U.S. Pat. Nos. 4,349,456, 4,565,556 and 4,605,594, each of which is hereby incorporated herein by reference, or polymeric materials such as polypropylene, poly(ethylene terephthalate), poly(propylene oxide), acrylic polymers, or polysulfone. In another embodiment of the invention, the partially transmissive granules are colored but have at least about 50% energy transmissivity to solar radiation over the 750-1150 nm wavelength range. Such granules may be, for example, substantially transparent particles having IR-transmissive coatings. The granules desirably have a size in the range of 0.2 mm to 3 mm.

Another aspect of the invention is a method of modifying a surface of a photovoltaic device comprising disposing on the surface of the photovoltaic device a polymer structure having granules disposed thereon. As the skilled artisan will appreciate, it may often be desirable to have the appearance of a photovoltaic element match, harmonize and/or complement that of a roofing material. As described above, the color of the polymer structure and the color(s) of the granules can be selected to provide a desirable appearance as well as sufficiently high transmissivity to solar radiation. The granules can be added to the polymer structure at any time (i.e., before, during or after the attachment of the polymer structure to the photovoltaic device). As the skilled artisan will understand, the polymer structure and granules can be selected substantially as described above.

It will be apparent to those skilled in the art that various modifications and variations can be made to the present invention without departing from the scope of the invention. Thus, it is intended that the present invention cover the modifications and variations of this invention provided they come within the scope of the appended claims and their equivalents.

What is claimed is:

1. A photovoltaic device comprising:
a photovoltaic element having an active face and an operating wavelength range;
a polymer structure having (a) a bottom surface disposed on the active face of the photovoltaic element and (b) a top surface; and
a plurality of granules disposed on the top surface of the polymer structure.

2. The photovoltaic device of claim 1, wherein the granules (a) are substantially opaque to radiation over the operating wavelength range of the photovoltaic element and (b) have a surface fill factor of no greater than about 75% over the active face of the photovoltaic element.

3. The photovoltaic device of claim 2, wherein the granules are ceramic-coated mineral core particles.

4. The photovoltaic device of claim 1, wherein the granules are at least partially transmissive to radiation over the operating wavelength range of the photovoltaic element.

5. The photovoltaic device of claim 4, wherein the granules transmit at least about 50% of solar radiation over the operating wavelength range of the photovoltaic element.

6. The photovoltaic device of claim 4, wherein the granules are made of glass.

7. The photovoltaic device of claim 6, wherein the granules are glass beads or glass cullet.

8. The photovoltaic device of claim 4, wherein the granules are made of quartz, sand, a non-vitreous ceramic, or a polymeric material.

9. The photovoltaic device of claim 4, wherein the granules are opaque to at least some visible radiation but have at least about 50% energy transmissivity to solar radiation over the 750-1150 nm wavelength range.

10. The photovoltaic device of claim 9, wherein at least some of the granules are partially transmissive granules coated with a near infrared transmissive coating.

11. The photovoltaic device of claim 1, wherein the granules have a size in the range from about 0.2 mm to about 3 mm.

12. The photovoltaic device of claim 1, wherein the polymer structure is a single layer of polymer.

13. The photovoltaic device of claim 1, wherein the polymer structure comprises a plurality of layers, wherein the layer distal to the active face of the photovoltaic element is a layer of polymer capable of adhering the granules.

14. The photovoltaic device of claim 1, wherein the polymer structure has an energy transmissivity to solar radiation of at least about 50% over the operating wavelength range of the photovoltaic element.

15. The photovoltaic device of claim 1, wherein the polymer structure has a thickness from about 50 μm to about 2 mm.

16. The photovoltaic device of claim 1, wherein the polymer structure is colored but has at least about 50% energy transmissivity to solar radiation over the 750-1150 nm wavelength range.

17. The photovoltaic device of claim 1, wherein the photovoltaic element is a monocrystalline silicon photovoltaic element or a polycrystalline silicon photovoltaic element.

18. The photovoltaic device of claim 1, wherein the combination of the polymer structure and the granules disposed thereon has an overall energy transmissivity to solar radiation of at least about 40% over the operating wavelength range of the photovoltaic element.

19. An array of photovoltaic devices of claim 1.

20. A photovoltaic roofing element, comprising a photovoltaic device of claim 1, disposed on or within a roofing substrate.

21. The photovoltaic roofing element of claim 20, wherein the roofing substrate is a roofing shingle, tile, panel, membrane or shake.

22. The photovoltaic roofing element of claim 20, wherein the roofing substrate is an asphalt roofing shingle.

23. The photovoltaic roofing element of claim 20, wherein the roofing substrate is a roofing membrane, a ceramic tile or a metal panel.

24. An array of photovoltaic roofing elements of claim 20.

25. A roof comprising one or more photovoltaic devices of claim 1 disposed on a roof deck.

26. A photovoltaic roofing element comprising
a roofing substrate having a top face and a bottom face;
a photovoltaic element disposed on the top face of or within the roofing substrate, leaving an exposed area on the top face of the roofing substrate, the photovoltaic element having an operating wavelength range and an active face, the active face having an active area and an inactive area;
a polymer structure having a bottom surface disposed on the exposed area on the top face of the roofing substrate, and a top surface; and
a plurality of granules disposed on the top surface of the polymer structure.

27. The photovoltaic roofing element of claim 26, wherein the polymer structure extends to cover the active area of the active face of the photovoltaic element.

28. The photovoltaic roofing element of claim 27, wherein the granules disposed on the polymer structure above the active area of the active face of the photovoltaic element are (a) substantially opaque to radiation over the operating wavelength range of the photovoltaic element, and (b) have a surface fill factor of no greater than about 75%.

29. The photovoltaic roofing element of claim 28, wherein the granules disposed on the polymer structure above the active area of the active face of the photovoltaic element are ceramic-coated mineral core particles.

30. The photovoltaic roofing element of claim 27, wherein the granules disposed on the polymer structure above the active area of the active face of the photovoltaic element are not substantially opaque to radiation over the operating wavelength range of the photovoltaic element.

31. The photovoltaic roofing element of claim 30, wherein the granules disposed on the polymer structure above the active area of the active face of the photovoltaic element transmit at least about 50% of solar radiation over the operating wavelength range of the photovoltaic element.

32. The photovoltaic roofing element of claim 30, wherein the granules disposed on the polymer structure above the active area of the active face of the photovoltaic element are made of glass.

33. The photovoltaic roofing element of claim 26, wherein the granules disposed on the polymer structure above the active area of the active face of the photovoltaic element have substantially the same composition and surface fill factor as the granules disposed on the polymer structure above the roofing substrate.

34. The photovoltaic roofing element of claim 26, wherein the granules disposed on the polymer structure above the active area of the active face of the photovoltaic element have a substantially different color distribution, composition and/or surface fill factor as the granules disposed on the polymer structure above the roofing substrate.

35. The photovoltaic roofing element of claim 26, wherein the polymer structure does not extend to cover the active area of the active face of the photovoltaic element.

36. The photovoltaic roofing element of claim 35, wherein the granules are substantially opaque to ultraviolet radiation and are colored.

37. The photovoltaic roofing element of claim 36, wherein the granules are ceramic-coated mineral core particles.

38. The photovoltaic roofing element of claim 36, wherein the granules have a surface fill factor of greater than about 50%.

39. The photovoltaic roofing element of claim 35, wherein the polymer structure is substantially opaque to ultraviolet radiation and is colored.

40. The photovoltaic roofing element of claim 35, further comprising a second polymer structure having a bottom surface disposed on the active face of the photovoltaic element, and a top surface; and a second plurality of granules disposed on the top surface of the second polymer structure.

41. The photovoltaic roofing element of claim 40, wherein the granules of the second plurality of granules are substantially opaque to radiation over the operating wavelength range of the photovoltaic element, and have a surface fill factor of no greater than about 75%.

42. The photovoltaic roofing element of claim 40, wherein the granules of the second plurality of granules are not substantially opaque to radiation over the operating wavelength range of the photovoltaic element.

43. The photovoltaic roofing element of claim 40, wherein the granules of the second plurality of granules are made of glass.

44. The photovoltaic roofing element of claim 26, wherein the photovoltaic element further comprises one or more electrical cables; and wherein the one or more electrical cables are disposed between the polymer structure and the roofing substrate.

45. The photovoltaic roofing element of claim 44, wherein the roofing substrate has a channel formed in its top face, and wherein the one or more electrical cables are disposed within the channel and covered by the polymer structure.

46. The photovoltaic roofing element of claim 26, wherein the roofing substrate is a roofing shingle, tile, panel, membrane or shake.

47. The photovoltaic roofing element of claim 26, wherein the roofing substrate is an asphalt shingle.

48. The photovoltaic roofing element of claim 26, wherein the roofing substrate is a roofing membrane, a ceramic tile or a metal panel.

49. A roof comprising one or more photovoltaic roofing elements according to claim 26 disposed on a roof deck.

50. A granule coated polymer structure comprising:
a polymer structure having a bottom surface and a top surface; and
a plurality of granules disposed on the top surface of the polymer structure, wherein the combination of the granules and the polymer structure has at least about 40% energy transmissivity of solar radiation in the 400-750 nm wavelength range, the 650-1000 nm wavelength range, or the 450-1150 nm wavelength range.

51. A method of modifying a surface of a photovoltaic device, the method comprising:
disposing on the surface of the photovoltaic device a polymer structure, the polymer structure having a bottom surface and a top surface, the bottom surface being disposed on the surface of the photovoltaic device, the top surface having granules disposed thereon.
